(19) United States
(12) Patent Application Publication
(10) Pub. No.: US 2018/0130871 A1
(43) Pub. Date: May 10, 2018

(54) CAPACITOR STRUCTURE AND MANUFACTURING METHOD THEREOF

(71) Applicant: UNITED MICROELECTRONICS CORP., Hsin-Chu City (TW)

(72) Inventors: Hung-Chan Lin, Tainan City (TW); Chin-Fu Lin, Tainan City (TW); Chun-Yuan Wu, Yun-Lin County (TW)

(21) Appl. No.: 15/346,717

(22) Filed: Nov. 8, 2016

(51) Int. Cl. H01L 49/02

(52) U.S. Cl. CPC H01L 28/88

(57) ABSTRACT

The present invention provides a capacitor structure, including a bottom plate and a top plate, wherein the top plate has a first sidewall, and wherein an area of the top plate is less than an area of the bottom plate. The capacitor structure further includes a dielectric layer in between the bottom plate and the top plate, the dielectric layer having a second sidewall, wherein the first sidewall is aligned with the second sidewall, and at least one sidewall spacer placed against the first sidewall of the top plate and the second sidewall of the dielectric layer, and overlaying a portion of the bottom plate.

### BACKGROUND OF THE INVENTION

### 1. Field of the Invention

The present invention relates in general to integrated circuitry and, in particular, to capacitors and their fabrication.

### 2. Description of the Prior Art

A capacitor is a passive two-terminal electrical component used to store energy electro-statically in an electric field. The forms of practical capacitors vary widely, but all contain at least two electrical conductors separated by a dielectric (insulator). Capacitors are widely used as parts of electrical circuits in many common electrical devices. For example, capacitors are widely used in electronic circuits for blocking direct current while allowing alternating current to pass, but can also be used to store data states, such as in a dynamic random access memory (DRAM) device.

For integrated circuits and for DRAM devices in particular, the use of metal-insulator-metal (MIM) capacitors has become widespread in recent years.

### SUMMARY OF THE INVENTION

The present invention provides a capacitor structure, including a bottom plate and a top plate, wherein the top plate has a first sidewall, and wherein an area of the top plate is less than an area of the bottom plate, a dielectric layer in between the bottom plate and the top plate, the dielectric layer having a second sidewall, wherein the first sidewall is aligned with the second sidewall, and at least one sidewall spacer placed against the first sidewall of the top plate and the second sidewall of the dielectric layer, and overlaying a portion of the bottom plate.

The present invention further provides a method for forming a capacitor structure, firstly, a bottom plate and a top plate are formed, wherein the top plate has a first sidewall, and wherein an area of the top plate is less than an area of the bottom plate, and a dielectric layer is formed between the bottom plate and the top plate, the dielectric layer having a second sidewall, wherein the first sidewall is aligned with the second sidewall, afterwards, at least one sidewall spacer is formed placed against the first sidewall of the top plate and the second sidewall of the dielectric layer, and the at least one sidewall spacer overlays a portion of the bottom plate.

The key feature of the present invention is to provide a new capacitor structure, the outer sidewall of the top plate is aligned with the outer sidewall of the dielectric layer, and the outer sidewall of the bottom plate is aligned with the outer sidewall of the spacer. The bottom plate is formed through a self-aligned etching process. Therefore, the size of the bottom plate can be minimized, thereby increasing the effective area of the capacitor structure. Besides, a repair process is performed during the manufacturing process, to repair a damaged portion (such as a notch) of the dielectric layer, thereby the leakage current of the capacitor structure can be prevented.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a side view of a substrate having a bottom via structure formed therein;

FIG. 2 illustrates a side view of a metal-insulator-metal (MIM) capacitor structure formed over the bottom via structure in accordance with the present invention;

FIG. 3 depicts a side view of a MIM capacitor structure after a top plate and the dielectric layer are etched;

FIG. 4 illustrates a side view of a MIM capacitor structure following performing a repair process to the dielectric layer;

FIG. 5 illustrates a side view of a MIM capacitor structure following formation of an insulating layer;

FIG. 6 depicts a side view of a MIM capacitor structure following formation of sidewall spacers that protect the dielectric layer; and

FIG. 7 illustrates a side view of a completed MIM capacitor in accordance with the present invention.

FIG. 8 illustrates a side view of a completed MIM capacitor in accordance with another preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

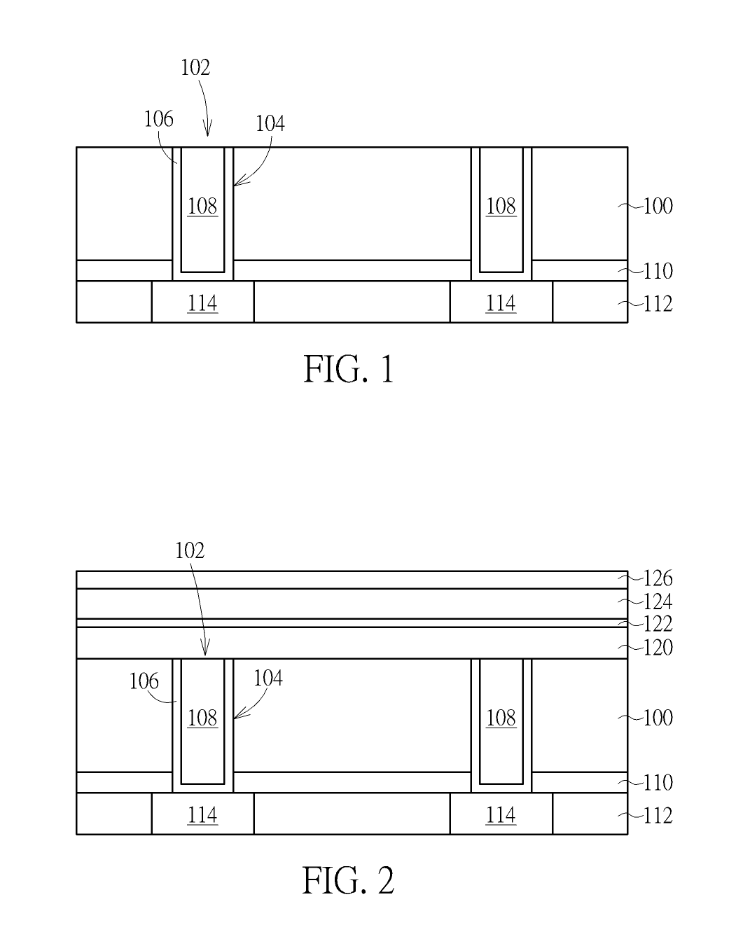

Please refer to FIG. 1, which depicts a cross section diagram of a substrate having a bottom via structure formed therein. As shown in FIG. 1, a substrate 100 is provided, and at least one bottom via structure 102 is formed in the substrate 100. The substrate 100 such as a silicon oxide layer, and the bottom via structure 102 is a contact structure including an opening 104 disposed in the substrate 100, and a barrier layer 106 and a conductive layer 108 are formed and disposed in the opening 104. Besides, the present invention may further comprise other elements disposed under the bottom via structure 102, for example, as shown in FIG. 1, the substrate 100 is not the bottommost layer, and the substrate 100 is disposed on other layers, such as on a material layer 110 (such as a silicon nitride layer) and on a material layer 112 (such as a silicon oxide layer), and the bottom via structure 102 is electrically connected to other elements (not shown) through a metal plug 114 which is disposed in the material layer 112. In the preferred embodiment, the metal plug 114 is formed of copper, although other metals such as gold or aluminum are also suitable.

However, in the present invention, the bottom via structure is not necessarily formed. In another case, the following-formed capacitor structure (not shown) is directly formed on the metal plug 114 mentioned above, and in this case, the substrate 100, the material layer 110 and the bottom via structure 102 can be omitted.

Next, as shown in FIG. 2, a bottom electrode material layer 120, a dielectric layer 122 and a top electrode material layer 124 are sequentially formed on the substrate 100 and on the bottom via structure 102. The bottom electrode material layer 120 and the top electrode material layer 124 preferably include a thin layer of aluminum (Al), tungsten (W) or other suitable metals, but not limited thereto. And the dielectric layer 122 preferably includes a silicon oxide layer, but not limited thereto. The bottom electrode material layer 120, the dielectric layer 122 and the top electrode material layer 124 are a metal-insulator-metal (MIM) stacked structure, and they will be etched to form the MIM capacitor structure of the present invention in the following steps.

In addition, the present invention may further include a plurality of barrier layers, such as tantalum nitride (TaN) layers (not shown), disposed between each layer mentioned above. For example, a barrier layer may be disposed between the bottom electrode material layer 120 and the dielectric layer 122, disposed between the top electrode material layer 124 and the dielectric layer 122, disposed above the top electrode material layer 124 or disposed under the bottom electrode material layer 120. The barrier layer retards diffusion of copper (or other metal) from the bottom via structure 102 into the following-formed capacitor's bottom/top plate and dielectric layer. The barrier layers mentioned above can be formed using any conventional process, such as chemical vapor deposition (CVD), sputtering, evaporation, etc. In some case, the barrier layers may be omitted from the MIM capacitor structure.

Besides, a hard mask material layer 126 is also formed on the top electrode material layer 124, the hard mask material layer 126 such as a silicon oxide layer, a silicon nitride layer or includes other suitable materials. The hard mask material layer 126 is formed on the top electrode material layer 124, to prevent the charge leakage of the following-formed capacitor.

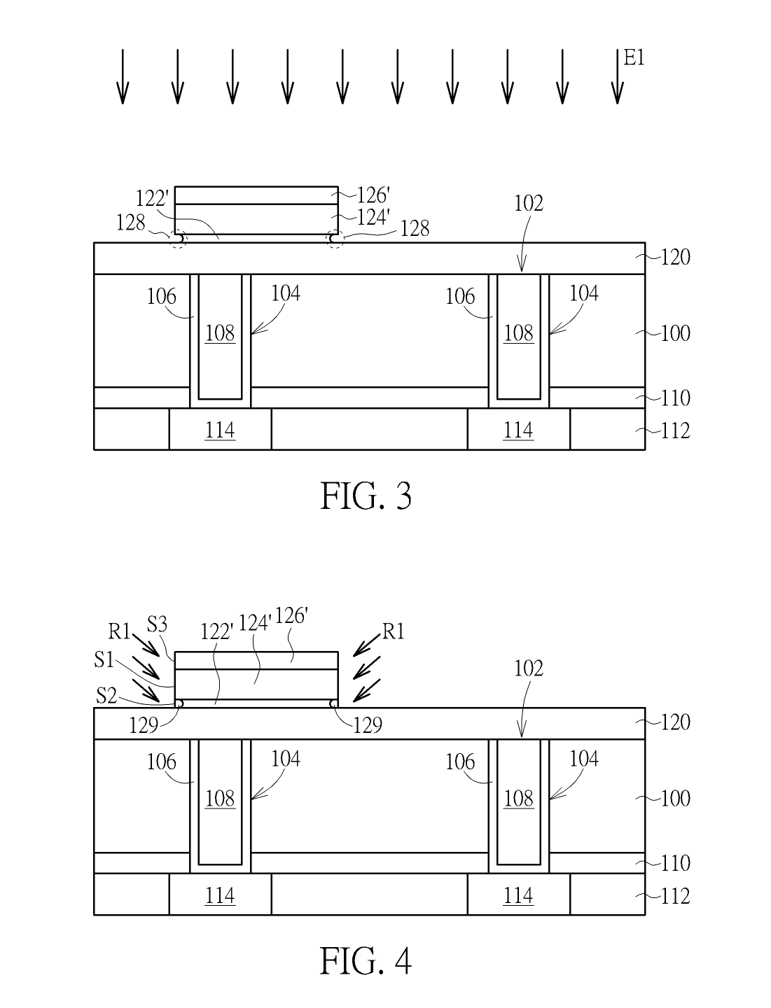

Afterwards, as shown in FIG. 3, an first etching process E1 is formed, the first etching process E1 may include a multiple steps etching process, to pattern the hard mask material layer 126 (to remove parts of the hard mask material layer 126), and the rest of the hard mask material layer 126 is defined as a hard mask layer 126′. Next, the hard mask layer 126′ is used as a protective layer, and the first etching process E1 is performed, to remove parts of the top electrode material layer 124 and parts of the dielectric layer 122, and stopped on the top surface of the bottom electrode material layer 120. The rest of the top electrode material layer 124 is defined as a top plate 124′, and the rest of the dielectric layer 122 is defined as a dielectric layer 122′.

It is noteworthy that during the first etching process E1, the dielectric layer 122′ may be damaged, especially in the edge portion of the dielectric layer 122′, after the a first etching process E1 is performed, and a damaged portion 128 is labeled in FIG. 3. In some case, the damaged portion 128 may be a notch, which may cause the leakage of the capacitor structure. In the present invention, as shown in FIG. 4, a repair process R1 is performed on the damaged portion 128, the repair process R1 being a process such as an ozone (O₃) treatment or an N₂O treatment to oxidize the sidewall of the dielectric layer 122′, so as to form an oxide layer filling in the damaged portion 128, and to repair the damaged portion 128. In one embodiment, an oxide edge portion 129 is filled in the damaged portion 128 (such as a notch), which surrounds the dielectric layer 122′, and the outer sidewall of the oxide edge portion 129 is aligned with the top plate 124′. In this way, the leakage current of the capacitor structure is therefore decreased. In the present invention, after the repair process R1 is performed, the outer sidewall of the top plate 124′ is defined as a first sidewall S1, and the outer sidewall of the oxide edge portion 129 is defined as a second sidewall S2, wherein the first sidewall S1 is aligned with the second sidewall S2. Besides, the outer sidewall of the hard mask layer 126′ is defined as a third sidewall S3, and the first sidewall S1 is aligned with the third sidewall S3 too.

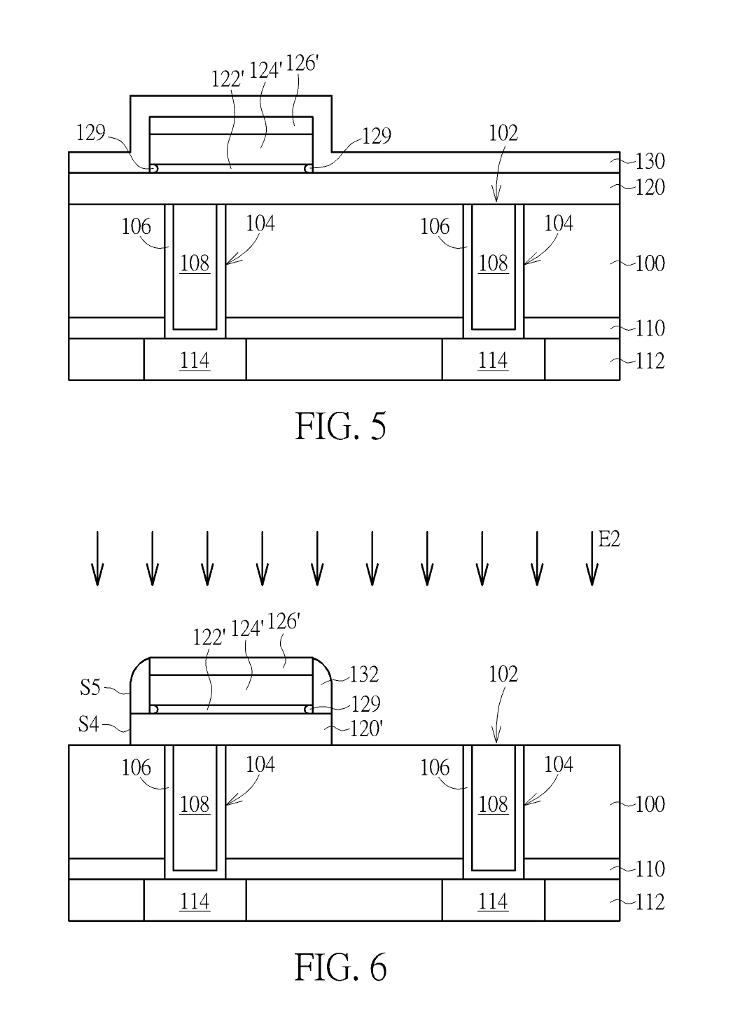

Afterwards, as shown in FIGS. 5 and 6, to further protect dielectric layer 122′ during later etching, a conformal layer of an insulator layer 130 such as silicon oxide layer is formed (e.g., deposited) on the hard mask layer 126′ and on the bottom electrode material layer 120. Next, as shown in FIG. 6, a second etching process E2 is performed, to remove parts of the insulator layer 130 and parts of the bottom electrode material layer 120, and to form at least two spacers 132 disposed on two sides of the dielectric layer 122′ respectively. When viewed in a cross section view, each spacer 132 is a sail shape structure, and the two spacers 132 also disposed on sidewalls of the hard mask layer 126′ and on sidewalls of the top plate 124′ too. The spacers 132 prevent contamination from the etching process contacting the top plate 124′.

It is noteworthy that the second etching process E2 may include a multiple steps etching processes. Firstly, an anisotropic etching process is carried out, to remove the parts of the insulator layer 130 (especially the insulator layer 130 that is disposed right above the hard mask layer 126′), but the two spacers 132 remain after the etching process. Next, another etching process is then carried out, and the remaining spacers 132 are used as the protective layer, to remove parts of the bottom electrode material layer 120. The rest of the bottom electrode material layer 120 is defined as a bottom plate 120′. Since the size and the location of the bottom plate 120′ is decided by the size and the position of the remaining spacers 132 (the spacers 132 is disposed on the bottom plate 120′), the second etching process is a self-aligned etching process, and the size of the bottom plate 120′ can be minimized (since only the bottom electrode material layer 120 that is disposed right under the spacers 132 and the dielectric layer 122′ are protected, the rest portions of the bottom electrode material layer 120 are entirely removed), thereby increasing the effective area of the capacitor structure.

As shown in FIG. 6, after the second etching process E2 is performed, the outer sidewall of the bottom plate 120′ is defined as a fourth sidewall S4, and the outer sidewall of the spacer 132 is defined as a fifth sidewall S5, wherein the fourth sidewall S4 is aligned with the fifth sidewall S5. In addition, the inner sidewall of the spacer 132 is aligned with the first sidewall S1 and the second sidewall S2 mentioned above. Besides, as shown in FIG. 6, an area of the top plate 124′ is smaller than an area of the bottom plate 120′.

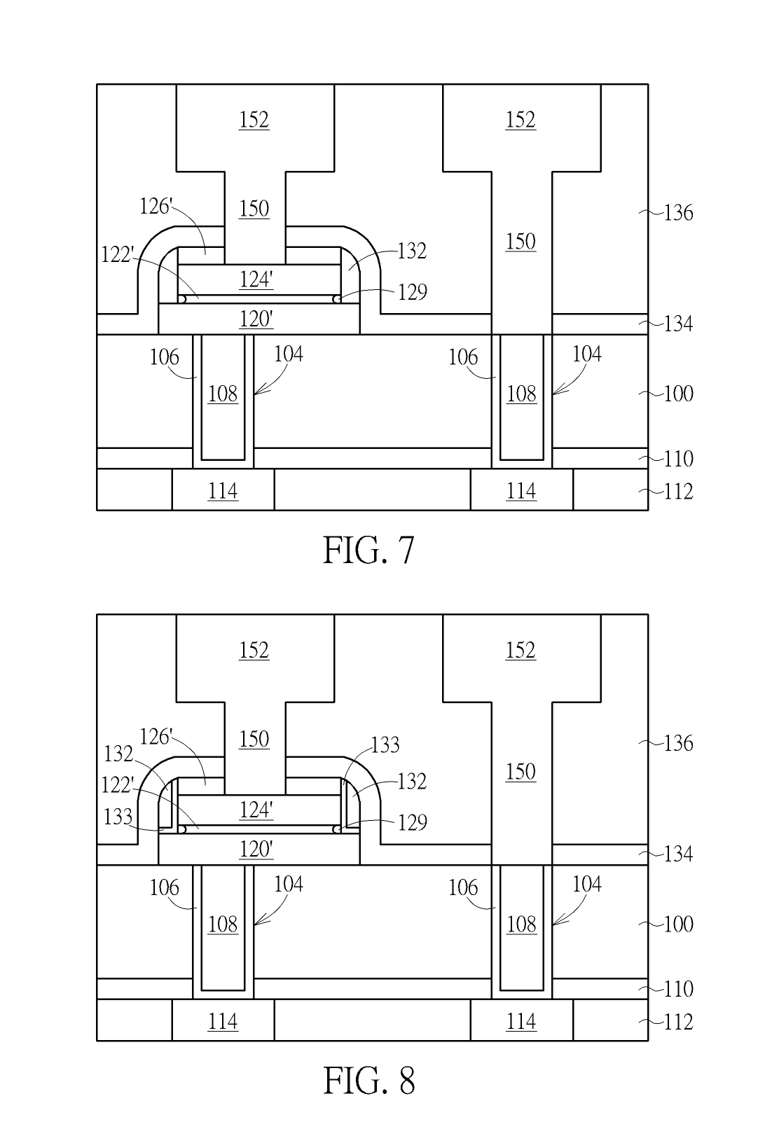

Finally, as shown in FIG. 7, a contact etching stop layer (CESL) 134, preferably made of silicon nitride (Si₃N₄), may be applied over the top and sides of the MIM capacitor using conventional deposition techniques such as those mentioned above to thereby surround portions of the capacitor stack (and specifically to surround the dielectric layer 120′). An inter-metal dielectric (IMD) 136 is then deposited over the entire MIM capacitor stack and may be subsequently planarized using processes well known in the art, such as CMP. The IMD 136 is disposed on the hard mask layer 126′ and on parts of the bottom plate 120′.

Thereafter, the MIM capacitor is electrically connected to at least one contact structure 150 to both top plate of the metal-insulator-metal capacitor and the bottom via structure 102 using processes well known in the art, such as lithographic masking, etching and conductive stud formation. The contact structure 150 penetrates the CESL 134 and the hard mask layer 126′ and to electrically connect the top plate 124′ of the MIM capacitor. Besides, the contact structure 150 may be further connected to a next layer of metal damascene wiring 152.

In another preferred embodiment of the present invention, please refer to FIG. 8, which illustrates a side view of a completed MIM capacitor in accordance with another preferred embodiment of the present invention. In this embodiment, the MIM capacitor has similarly structure to the MIM capacitor shown in the first preferred embodiment mentioned above (please refer to FIG. 7). The main difference between the MIM capacitor of this embodiment and the MIM capacitor of the first preferred embodiment is that the MIM capacitor of this embodiment further comprises at least one second spacer 133 disposed under the spacer 132. More precisely, after the top plate 124′ and the dielectric layer 122′ are patterned (as shown in FIG. 3), and before the insulator layer 130 (the material layer of the spacer 132) is formed, a second material layer (not shown) can be entirely formed through a thermal process (an oxidation process) or a plasma process, covering on the bottom electrode material layer 120 and on the hard mask layer 126′. Afterwards, the following processes mentioned in the first preferred embodiment are sequentially performed, including forming the insulator layer 130, etching the insulator layer 130 and the bottom electrode material layer 120, forming the CESL 134, forming the IMD 136 and forming the contact structures 150. Therefore, as shown in FIG. 8, when viewed in a cross section view, the second spacer 133 is an L-shaped structure, disposed under the sail shaped spacer 132. The second spacer 133 may include an oxide layer, but not limited thereto. Except for the features mentioned above, the other components, material properties, and manufacturing method of this embodiment are similar to the first preferred embodiment detailed above and will not be redundantly described.

In summary, the key feature of the present invention is to provide a new capacitor structure, the outer sidewall of the top plate is aligned with the outer sidewall of the dielectric layer, and the outer sidewall of the bottom plate is aligned with the outer sidewall of the spacer. The bottom plate is formed through a self-aligned etching process, therefore, the size of the bottom plate can be minimized, thereby increasing the effective area of the capacitor structure. Besides, a repair process is performed during the manufacturing process, to repair a damaged portion (such as a notch) of the dielectric layer, thereby the leakage current of the capacitor structure can be prevented.

Those skilled in the art will readily observe that numerous modifications and alterations of the device and method may be made while retaining the teachings of the invention. Accordingly, the above disclosure should be construed as limited only by the metes and bounds of the appended claims.

1. A capacitor structure, comprising:
a bottom plate and a top plate, wherein the top plate has a first sidewall, and wherein an area of the top plate is less than an area of the bottom plate;
a dielectric layer in between the bottom plate and the top plate, the dielectric layer having a second sidewall, wherein the first sidewall is aligned with the second sidewall; and
at least one sidewall spacer placed against the first sidewall of the top plate and the second sidewall of the dielectric layer, and overlaying a portion of the bottom plate, wherein the at least one sidewall spacer contacts the bottom plate, the top plate and the dielectric layer directly.

2. The capacitor structure of claim 1, further comprising:
a substrate underlying the bottom plate; and
a bottom via structure embedded in the substrate and underlying the bottom plate.

3. The capacitor structure of claim 1, wherein each of the bottom plate and the top plate comprises a metal plate.

4. The capacitor structure of claim 1, wherein the dielectric layer comprises a center portion and a repaired portion disposed surrounding the center portion.

5. The capacitor structure of claim 1, further comprising a hard mask layer overlaying the top plate.

6. The capacitor structure of claim 5, wherein the hard mask layer has a third sidewall, and the third sidewall is aligned with the first sidewall and the second sidewall.

7. The capacitor structure of claim 5, further comprising a contact etching stop layer, disposed on the hard mask layer and on the bottom plate.

8. The capacitor structure of claim 5, further comprising a contact structure penetrating the hard mask layer and directly contacting the top plate.

9. The capacitor structure of claim 1, wherein the at least one sidewall spacer has an outer sidewall, the bottom plate has a fourth sidewall, and the outer sidewall of the at least one sidewall spacer is aligned with the fourth sidewall.

10. The capacitor structure of claim 1, wherein the sidewall spacer comprises an outer spacer and an inner spacer disposed under the outer spacer.

11. A method for forming a capacitor structure, comprising:
forming a bottom plate and a top plate, wherein the top plate has a first sidewall, and wherein an area of the top plate is less than an area of the bottom plate;
forming a dielectric layer between the bottom plate and the top plate, the dielectric layer having a second sidewall, wherein the first sidewall is aligned with the second sidewall; and
forming at least one sidewall spacer placed against the first sidewall of the top plate and the second sidewall of the dielectric layer, and the at least one sidewall spacer overlays a portion of the bottom plate, wherein the at least one sidewall spacer contacts the bottom plate, the top plate and the dielectric layer directly.

12. The method of claim 11, further comprising:
providing a substrate underlying the bottom plate; and
forming a bottom via structure embedded in the substrate and underlying the bottom plate.

13. The method of claim 11, wherein after the top plate is formed, at least one notch is formed in the edge of the dielectric layer.

14. The method of claim 13, further comprising performing a repair process, so as form a repaired portion in the notch.

15. The method of claim 11, further comprising forming a hard mask layer overlaying the top plate.

16. The method of claim 15, wherein the hard mask layer has a third sidewall, and the third sidewall is aligned with the first sidewall and the second sidewall.

17. The method of claim 15, further comprising a contact etching stop layer, disposed on the hard mask layer and on the bottom plate.

18. The method of claim 15, further comprising a contact structure penetrating the hard mask layer and directly contacting the top plate.

19. The method of claim 11, wherein the at least one sidewall spacer has an outer sidewall, the bottom plate has a fourth sidewall, and the outer sidewall of the at least one sidewall spacer is aligned with the fourth sidewall.

20. The method of claim 11, further comprising forming a second spacer under the at least one sidewall spacer, wherein the second spacer contacts the top plate, the bottom plate and the dielectric layer directly.
